(19) United States
(12) Patent Application Publication
(10) Pub. No.: US 2018/0081801 A1
(43) Pub. Date: Mar. 22, 2018

(54) MEMORY SYSTEM AND PROCESSING SYSTEM

(71) Applicant: Toshiba Memory Corporation, Tokyo (JP)

(72) Inventors: Hiroki NOGUCHI, I, Yokohama (JP); Shinobu FUJITA, Tokyo (JP)

(73) Assignee: Toshiba Memory Corporation, Tokyo (JP)

(21) Appl. No.: 15/457,557

(22) Filed: Mar. 13, 2017

(30) Foreign Application Priority Data
Sep. 20, 2016 (JP) 2016-183393

(51) Int. Cl. G06F 12/02; G11C 11/4091; G11C 11/406; G11C 11/4096

(52) U.S. Cl. CPC G06F 12/0284; G11C 11/4091; G06F 2212/251; G11C 11/4096; G11C 11/406

(57) ABSTRACT

According to one embodiment, a memory system includes a first memory, a second memory, a third memory, and a controller. The controller executes a second access to the second memory in a first case, where the first case is a case in which a command for executing the first access to a first address is issued and data corresponding to the first address is stored in the second memory executes a third access to a second address in a second case, where the second case is a case in which the command is issued and the data corresponding to the first address is stored in the second address of the third memory, and executes a fourth access to a third address in a third case, where the third case is a case in which the command is issued, the command indicates a write operation to the first address.

### CROSS-REFERENCE TO RELATED APPLICATIONS

This application is based upon and claims the benefit of priority from Japanese Patent Application No. 2016-183393, filed Sep. 20, 2016, the entire contents of which are incorporated herein by reference.

### FIELD

Embodiments described herein relate generally to a memory system and a processor system.

### BACKGROUND

In a memory system including a host processor and a main memory, the main memory includes, for example, DRAM (dynamic random access memory). However, DRAM has a property that it is necessary to periodically refresh DRAM to hold data. Thus, when DRAM is used as the main memory, the data transfer capability between the host processor and the main memory is limited by the refresh of DRAM.

### BRIEF DESCRIPTION OF THE DRAWINGS

FIG. 1 is a diagram showing an example of a memory system;

FIG. 2 is a diagram showing an example of the memory system;

FIG. 3 is a diagram showing an example of the memory system;

FIG. 4 is a diagram showing an example of the memory system;

FIG. 5 is a diagram showing an example of data transfer between three memories;

FIG. 6 is a diagram shooing an example of DRAM;

FIG. 7 is a diagram showing an example of a buffer memory (sense amplifier of DRAM);

FIG. 8 is a diagram showing an example of a redeem memory;

FIG. 9 is a diagram showing an example of a sense amplifier of the redeem memory;

FIG. 10 is a flowchart showing an example of memory access controlling;

FIG. 11A is a diagram visualizing the memory access controlling in FIG. 10;

FIG. 11B is a diagram visualizing the memory access controlling in FIG. 10;

FIG. 11C is a diagram visualizing the memory access controlling in FIG. 10;

FIG. 12 is a flowchart showing the memory access controlling as a comparative example;

FIG. 13 is a flowchart showing an example of memory space controlling of a redeem memory;

FIG. 14 is a diagram visualizing the memory space controlling of the redeem memory in FIG. 13;

FIG. 15 is a flowchart showing a condition for the memory space controlling of the redeem memory;

FIG. 16 is a flowchart showing a condition for the memory space controlling of the redeem memory;

FIG. 17 is a flowchart showing an example of a write back operation from the redeem memory to DRAM;

FIG. 18 is a diagram showing a first application example;

FIG. 19 is a diagram showing a second application example;

FIG. 20 is a diagram showing a third application example;

FIG. 21 is a diagram showing a fourth application example;

FIG. 22 is a diagram showing LUT (buffer memory hit table);

FIG. 23 is a diagram showing LUT (redeem memory hit table); and

FIG. 24 is a diagram showing LUT (redeem memory hit table).

### DETAILED DESCRIPTION

In general, according to one embodiment, a memory system comprises: a first memory including a first address; a second memory being capable of storing data corresponding to the first address of the first memory; a third memory; and a controller controlling an access to the first, second and third memories. The controller is configured to: execute a second access to the second memory instead of a first access in a first case, where the first case is a case in which a command for executing the first access to the first address is issued and the data corresponding to the first address is stored in the second memory; execute a third access to a second address of the third memory instead of the first access in a second case, where the second case is a case in which the command is issued and the data corresponding to the first address is stored in the second address of the third memory; and execute a fourth access to a third address of the third memory instead of the first access in a third case, where the third case is a case in which the command is issued, the command indicates a write operation to the first address and the first and second cases are excluded.

Hereinafter, embodiments will be described with reference to the drawings.

### Memory System

FIGS. 1 to 4 show memory system examples.

The memory system to which the present example is applied includes a processor (host) 10 and a main memory 11.

Memory systems include, for example, electronic devices including personal computers and mobile terminals, imaging apparatuses including digital still cameras and video cameras, tablet computers, smartphones, game machines, car navigation systems, printer devices, scanner devices, and server systems.

In the example of FIG. 1, the processor 10 includes a CPU 12, a cache memory 13, and a controller 14 and the controller 14 includes a LUT (look-up table) 15. The main memory 11 includes a DRAM M_{D}, a buffer memory M_{B}, and a redeem memory M_{R}.

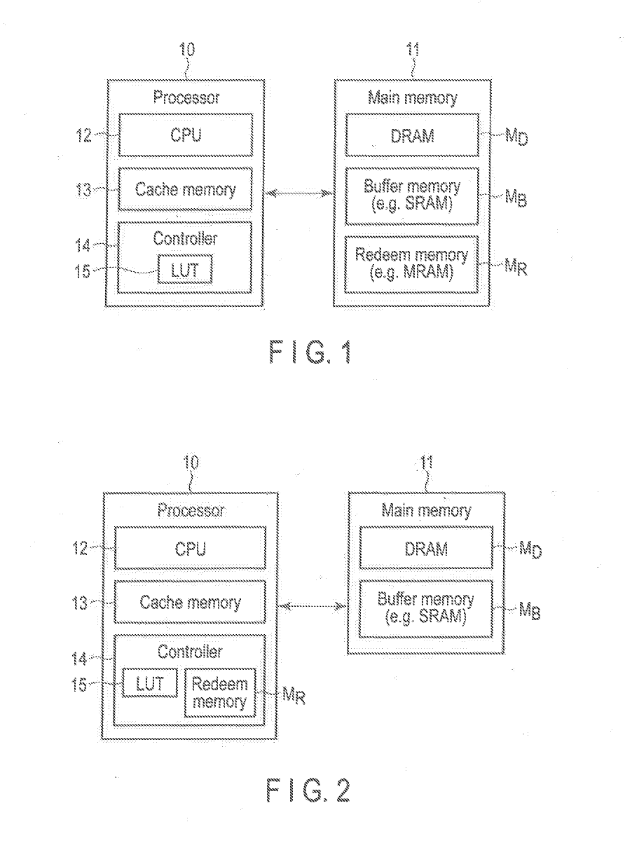

In the example of FIG. 2, the processor 10 includes the CPU 12, the cache memory 13, and the controller 14 and the controller 14 includes the LUT 15 and the redeem memory M_{R}. The main memory 11 includes the DRAM M_{D} and the buffer memory M_{B}.

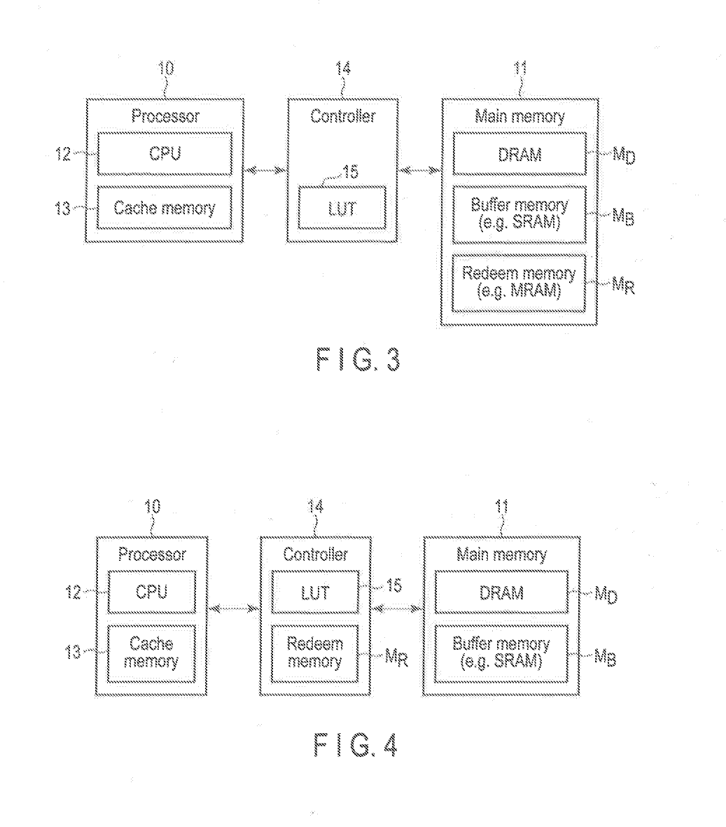

In the example of FIG. 3, the processor 10 includes the CPU 12 and the cache memory 13. The main memory 11 includes the DRAM M_{D}, the buffer memory M_{B}, and the redeem memory M_{R}. The controller 14 is connected between the processor 10 and the main memory 11 and includes the LUT 15.

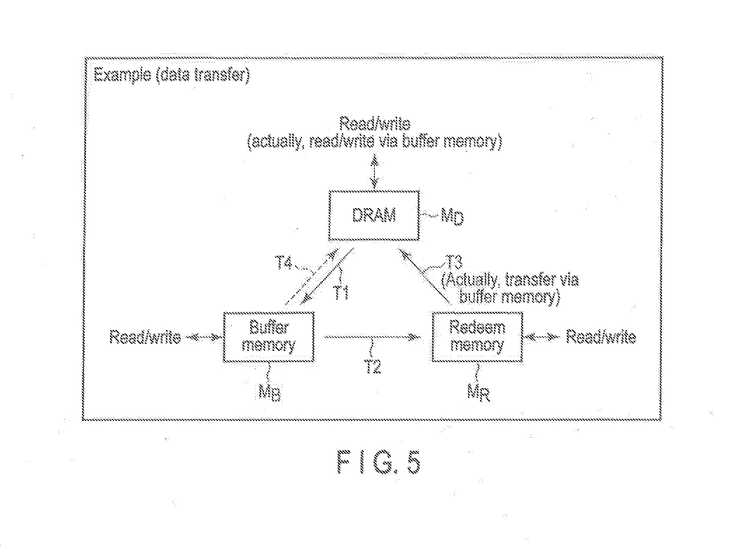

In the example of FIG. 4, the processor 10 includes the CPU 12 and the cache memory 13. The main memory 11 includes the DRAM M_{D} and the buffer memory M_{B}. The controller 14 is connected between the processor 10 and the main memory 11 and includes the LUT 15 and the redeem memory M_{R}.

The CPU 12 includes, for example, a plurality of CPU cores. The plurality of CPU cores are elements capable of performing different data processes in parallel. In recent years, throughput of the processor 10 has improved due to an increased number of CPU cores (for example, eight cores or 16 cores) and the memory capacity of the main memory 11 has increased (for example, 100 GB or the like) and therefore, improvements of the data transfer capability between the processor 10 and the main memory 11 have become an urgent problem.

The cache memory 13 is one technology to solve the problem. The cache memory 13 includes, for example, SRAM (static random access memory) capable of high-speed access and solves the problem by caching data stored in the DRAM M_{D}. However, it is difficult to achieve an increased capacity of SRAM due to large standby power and a large cell area.

Thus, a memory system according to the present embodiment includes three types of memories, for example, the DRAM M_{D}, the buffer memory M_{B}, and the redeem memory M_{R}.

The DRAM M_{D} is the formal storage location of data in the main memory 11. The buffer memory M_{B} and the redeem memory M_{R} are elements for the processor 10 to access data stored in the DRAM M_{D} at high speed.

The buffer memory M_{B} is, for example, SRAM. The buffer memory M_{B} functions as, for example, a sense amplifier of the DRAM M_{D}.

The DRAM M_{D} and the buffer memory M_{B} have the following characteristics:

The DRAM M_{D} is accessed by activating one row in a memory cell array. Activating one row means turning on one row, that is, a select transistor in the memory cell connected to one word line. An operation of activating one row is called, for example, a row-open operation or a page-open operation. One activated row is called, for example, an opened row or an opened page.

On the other hand, deactivating one row in the DRAM M_{D} means turning off one row, that is, a select transistor in the memory cell connected to one word line. An operation of deactivating one row is called, for example, a row-close operation or a page-close operation. One deactivated row is called, for example, a closed row or a closed page. In a state in which one row is deactivated, a precharge operation of bit lines or the like is performed in preparation for the next access.

The buffer memory M_{B} can store, for example, data (hereinafter, called page data) stored in a plurality of memory cells in one activated row (a plurality of memory cells connected to one word line) of the DRAM M_{D}. The buffer memory M_{B} functions as a cache memory having a memory hierarchy between the memory hierarchy of the cache memory (for example, L1 to L3 caches) 13 in the processor 10 and the memory hierarchy of the DRAM M_{D} in the main memory 11.

If for example, data to be accessed is stored in the buffer memory M_{B} (in the case of a buffer memory hit), the processor 10 makes access to the main memory 11 faster by accessing the buffer memory M_{B} without accessing the DRAM M_{D}.

The redeem memory M_{R} is an element that enables a read/write operation of data to be accessed without accessing the DRAM M_{D}, that is, performing a page-open/close operation (row-open/close operation) in the DRAM M_{D} even if data to be accessed is not stored in the buffer memory M_{B} (in the case of a buffer memory miss).

In the case of, for example, a buffer memory miss, first the DRAM M_{D} needs to perform a page-close operation and then, perform a page-open operation to access a new page (row) to be accessed. However, such a page-open/close operation delays access to the main memory 11.

Thus, if data to be accessed is stored in the redeem memory M_{R} (in the case of a redeem memory hit) even if a buffer memory miss occurs, a read/write operation of data to be accessed is currently made executable in the redeem memory M_{R} by postponing access to the DRAM M_{D}, that is, postponing a page-open/close operation (row open/close operation) in the DRAM M_{D}.

Also in a write operation, even if a buffer memory miss occurs and data to be accessed is not stored in the redeem memory M_{R} (in the case of a redeem miss), access to the DRAM M_{D}, that is, a page-open/close operation (row open/close operation) in the DRAM M_{D} can currently be postponed by causing the redeem memory M_{R} to store write data.

The redeem memory M_{R} has the same memory hierarchy as that of the buffer memory M_{B}. That is, the redeem memory M_{R} functions, like the buffer memory M_{B}, as a cache memory having a memory hierarchy between the memory hierarchy of the cache memory 13 in the processor 10 and the memory hierarchy of the DRAM M_{D} in the main memory 11.

The memory hierarchy of the redeem memory M_{R} and that of the buffer memory M_{B} are the same and thus, data of the same address managed by the processor 10 will not be stored in these two memories at the same time.

That is, even if both of the DRAM M_{D} as a formal storage location of data in the main memory 11 and the buffer memory M_{B} as a cache memory or both of the DRAM M_{D} as a formal storage location of data in the main memory 11 and the redeem memory M_{R} as a cache memory may store data of the same address at the same time, but both of the redeem memory M_{R} and the buffer memory M_{B} does not store data of the same address at the same time.

The redeem memory M_{R} functions as a cache memory of the main memory 11 and so is desirably a memory capable of high-speed access. Also, in view of memory access controlling described below, the redeem memory M_{R} desirably has a memory capacity larger than that of the buffer memory M_{B}. Further, to reduce power consumption of the memory system and eliminate access constraint due to refresh or the like, the redeem memory M_{R} is desirably a nonvolatile memory or a volatile memory having a very long data retention time.

Such memories include, for example, nonvolatile RAM such as an MRAM (magnetic random access memory) and ReRAM (resistance change memory) and a DRAM (ULR DRAM: Ultra Long Retention DRAM) in which an oxide semiconductor (for example, IGZO) is used as a channel of a select transistor in a memory cell.

Page data stored in the buffer memory M_{B} is updated when, for example, a buffer memory hit occurs in a write operation. Thus, page data in the buffer memory M_{B} is what is called dirty data that is not written back to the DRAM M_{D} as the formal storage location while being updated by, for example, a write operation.

Similarly, page data stored in the redeem memory M_{R} is updated when, for example, a redeem memory hit occurs in a write operation. Thus, page data in the redeem memory M_{R} is what is called dirty data that is not written back to the DRAM M_{D} as the formal storage location while being updated by, for example, a write operation.

Such dirty data is made clean data by writing back to the DRAM M_{D} as the formal storage location in the end.

In a memory system according to the present embodiment, for example, as shown in FIG. 5, data transfer between three types of memories, that is, the DRAM M_{D}, the buffer memory M_{B}, and the redeem memory M_{R} is controlled like a loop.

First, page data in the DRAM M_{D} is mowed into the buffer memory M_{b} by, for example, a page-open operation (arrow T1 in FIG. 5). Next, page data in the buffer memory M_{B} is moved into the redeem memory M_{R} by, for example, a page-close operation (arrow T2 in FIG. 5). Lastly, page data in the redeem memory M_{R} is written back to the DRAM M_{D} at a predetermined time (arrow T3 in FIG. 5).

The predetermined time when page data in the redeem memory M_{R} is written back to the DRAM M_{D} is, for example, after free space runs out in the redeem memory M_{R}. If there is no need to immediately write new page data into the redeem memory M_{R} even after free space runs out in the redeem memory M_{R}, page data in the redeem memory M_{R} is written back to the DRAM M_{D} when a predetermined condition is satisfied after free space runs out in the redeem memory M_{R} because performance (data throughput) of the processor 10 is not affected.

The predetermined condition is, for example, there is no access to the main memory 11 for a fixed period or the DRAM M_{D} is refreshed and a page to be refreshed is present in the redeem memory M_{R}.

The predetermined time when page data in the redeem memory M_{R} is written back into the DRAM M_{D} may be, for example, a time when the amount of data processed in the processor 10 is small. This is because the amount of data transferred between the processor 10 and the main memory 11 at such a time is also small and a page-open/close operation in the DRAM M_{D} does not affect performance of the processor 10.

Such a time is, for example, after the processor (a plurality of CPU cores) 10 enters a power save mode, after, among a plurality of CPU cores in the processor 10, the number of CPU cores in an operating state is equal to a predetermined number or less, when the current throughput of data is a predetermined percentage or less if the maximum data throughput of the processor (a plurality of CPU cores) 10 is 100%, or after it becomes necessary to write back data in the DRAM M_{D} to a storage device (such as HDD, SSD or the like) when power of the memory system (DRAM M_{D}) is cut off or the like.

When it becomes necessary to write data in the DRAM M_{D} back to a storage device, page data in the buffer memory M_{B} is not moved into the redeem memory M_{R} by a page-close operation. In this case, page data in the buffer memory M_{B} is written back into the DRAM M_{D} before a page-close operation (arrow T4 in FIG. 5). Also after the page-close operation, page data in the redeem memory M_{R} is written back into the DRAM M_{D} (arrow T3 in FIG. 5).

According to such a set of data controlling, for example, in a period in which the processor 10 performs data processing, an occurrence of the page-open/close operation in the DRAM M_{D} is suppressed. Thus, in such a period, the data transfer capacity between the processor 10 and the main memory 11 is improved, leading to improved performance of the memory system. The above data controlling is controlled by the controller 14. The controller 14 includes the LUT 15 indicating where valid data is located to execute such data controlling. The LUT 15 may store data in RAM of the processor 10 to acquire the data therefrom or store data in the DRAM M_{D} to acquire the data therefrom. A concrete example of the data controlling by the controller 14 will be described below.

### DRAM

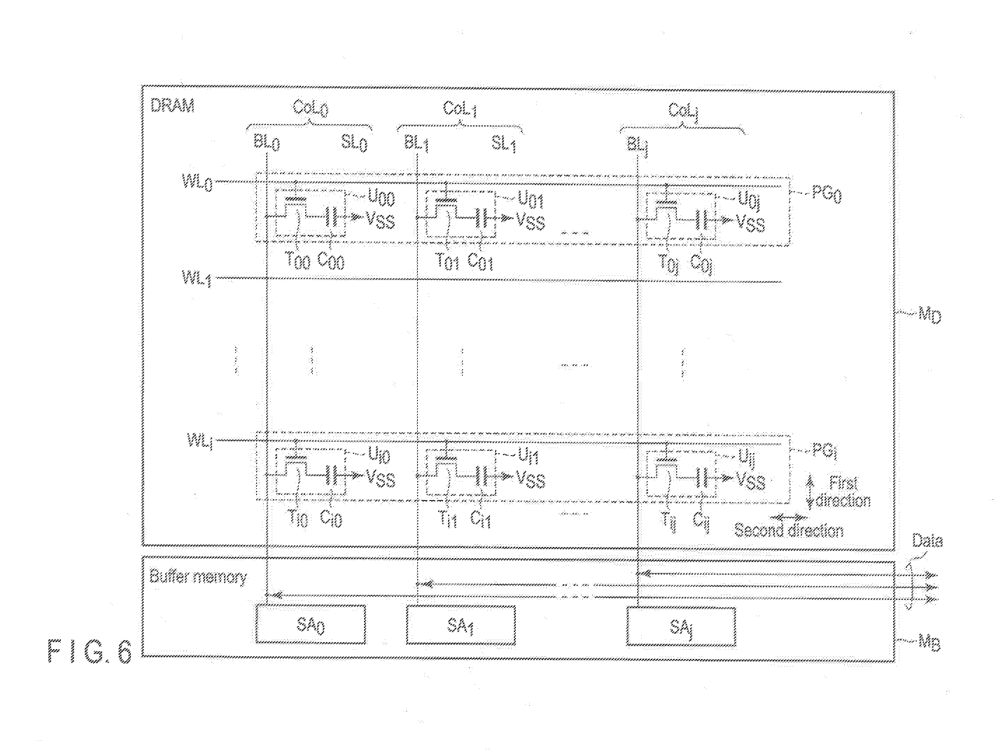

FIG. 6 shows an example of DRAM.

The DRAM M_{D} includes a plurality of memory cells U₀₀ to Uᵢⱼ arranged like an array. The buffer memory M_{B} is a sense amplifier SAⱼ of the DRAM M_{D}.

One memory cell Uᵢⱼ includes a capacitor Cᵢⱼ and a transistor (FET: Field Effect Transistor) Tᵢⱼ connected in series, where i is, for example, 0, 1, 2, . . . , 1023 and j is, for example, 0, 1, 2, . . . , 4095.

The capacitor Cᵢⱼ includes first and second electrodes and the transistor Tᵢⱼ includes a current path having first and second terminals and a control terminal to control ON/OFF of the current path. The first terminal of the transistor Tᵢⱼ is connected to the first electrode of the capacitor Cᵢⱼ.

A bit line BLⱼ is connected to the second terminal of the transistor Tᵢⱼ and extends in a first direction. The bit line BLⱼ is connected to the buffer memory M_{B}, that is, the sense amplifier SAⱼ. A word line WLᵢ is connected to the control terminal of the transistor Tᵢⱼ and extends in a second direction perpendicular to the first direction. The second electrode of the capacitor Cᵢⱼ is set to, for example, a ground potential Vₛₛ.

A plurality of memory cells Uᵢ₀ to Uᵢⱼ connected to the word line WLᵢ belongs to one group, for example, a page PGᵢ. Data stored in the memory cells Uᵢ₀ to Uᵢⱼ in the page PGᵢ is page data. In the DRAM M_{D}, the page-open/close operation is performed in units of pages.

A plurality of sense amplifiers SA₀ to SAⱼ is provided by corresponding to a plurality of columns CoL₀ to CoLⱼ.

In the DRAM M_{D} described above, a write operation is performed by, for example, changing the bit line BLⱼ from a precharge potential (for example, V_{dd}/2) to the potential in accordance with the value of write data.

When, for example, 1-bit data (0 or 1) is written into the memory cell Uᵢⱼ, the ground potential Vₛₛ may be transferred from the sense amplifier SAⱼ to the bit line BLⱼ when the write data is 0 and a power supply potential V_{dd} may be transferred from the sense amplifier SAⱼ to the bit line BLⱼ when the write data is 1.

For a read operation, for example, the bit line BLⱼ may be set to a precharge potential (for example, V_{dd}/2) and floated. In this case, if the word line WLᵢ is activated, the potential of the bit line BLⱼ changes in accordance with data stored in the memory cell Uᵢⱼ, the amount of charges accumulated in the capacitor Cᵢⱼ.

Data (read data) stored in the memory cell Uᵢⱼ can be detected by sensing potential changes of the bit line BLⱼ through the sense amplifier SAⱼ.

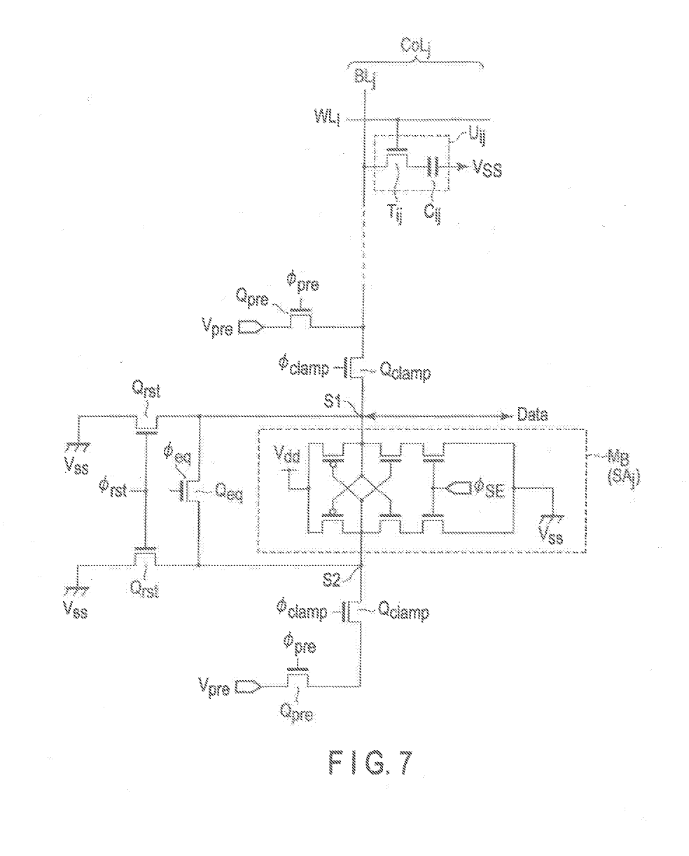

FIG. 7 shows an example of a buffer memory.

The buffer memory M_{B} is a sense amplifier SAⱼ of the DRAM M_{D}.

A memory cell Uᵢⱼ, a capacitor Cᵢⱼ, a transistor Tᵢⱼ, a word line WLᵢ, and a bit line BLⱼ correspond to the memory cell Uᵢⱼ, the capacitor Cᵢⱼ, the transistor Tᵢⱼ, the word line WLᵢ, and the bit line BLⱼ shown in FIG. 6 respectively.

Qₚᵣₑ is a transistor (for example, an N channel FET) to apply a precharge potential Vₚᵣₑ to the bit line BLⱼ in a read/write operation (page-close operation). In a read/write operation, for example, when a control signal φₚᵣₑ is activated (for example, set to a high level), the transistor Qₚᵣₑ is turned on and Vₚᵣₑ=V_{dd}/2 is transferred to the bit line BLⱼ. When the control signal φₚᵣₑ is deactivated (for example, set to a low level), the transistor Qₚᵣₑ is turned off.

Q_{clamp} functions as a switching element (clamp circuit) to electrically connect the bit line BLⱼ to the sense amplifier SAⱼ in a read/write operation. Q_{clamp} is, for example, an N channel FET. When the control signal φ_{clamp} is activated in a read/write operation, the transistor Q_{clamp} is turned on and the bit line BLⱼ and the sense amplifier SAⱼ are electrically connected. When the control signal φ_{clamp} is deactivated, the transistor Q_{clamp} is turned off.

The sense amplifier SAⱼ includes SRAM, that is, two flip-flopped inverter circuits. When a control signal (sense amplifier enable signal) φ_{SE} is activated, the sense amplifier SAⱼ is put into an activating state. When the control signal φ_{SE} is deactivated, the sense amplifier SAⱼ is put into a non-activating state.

The sense amplifier SAⱼ includes two input/output nodes S1, S2. Read/write data is input/output through, for example, the input/output node S1.

Q_{eq} is a transistor (equalizing circuit) that equalizes the potentials of the two input/output nodes S1, S2. Q_{eq} is, for example, an N channel FET. When a control signal φ_{eq} is activated, a transistor Q_{eq} is turned on and the potentials of the two input/output nodes S1, S2 are equalized. When the control signal φ_{eq} is deactivated, the transistor Q_{eq} is turned off.

Qᵣₛₜ is a transistor (for example, an N channel FET) that resets the potentials of the two input/output nodes S1, S2. When a control signal φᵣₛₜ is activated, a transistor Qᵣₛₜ is turned on and the potentials of the two input/output nodes S1, S2 are reset. When the control signal φᵣₛₜ is deactivated, the transistor Qᵣₛₜ is turned off.

### Redeem Memory

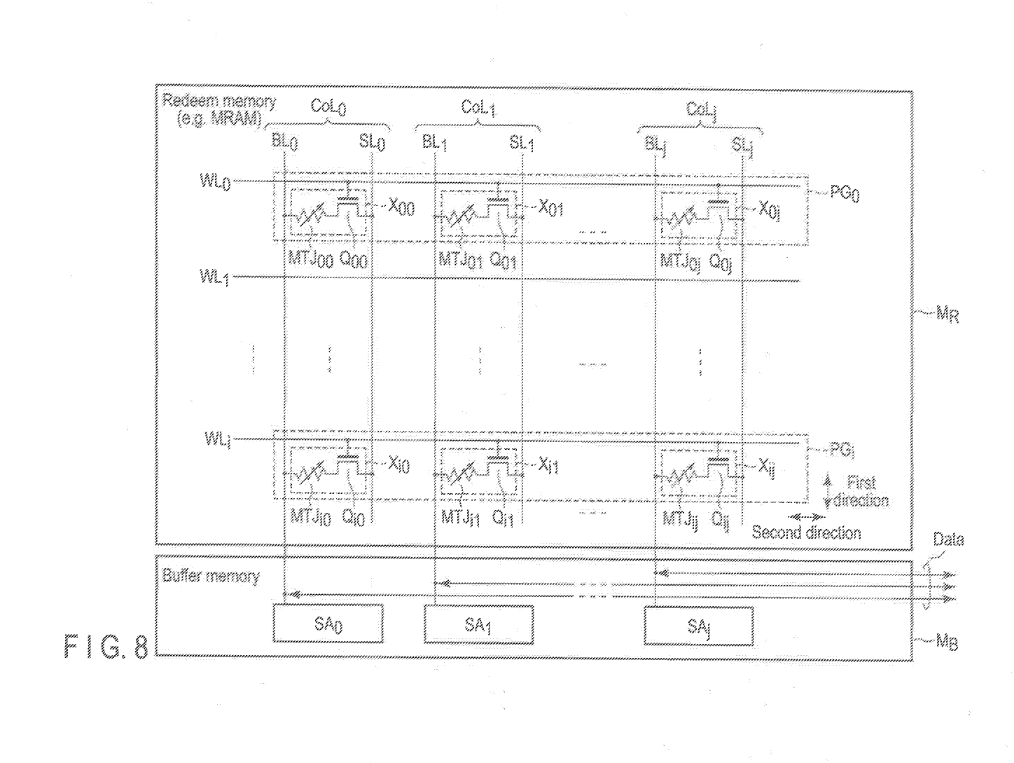

FIG. 8 shows an example of a redeem memory.

In the present example, the redeem memory M_{R} is MRAM. Also, like the DRAM M_{D} described above, the sense amplifier SAⱼ of the redeem memory M_{R} can be used as the buffer memory M_{B}. However, the sense amplifier SAⱼ of the redeem memory M_{R} may not be used as the buffer memory M_{B}.

The redeem memory M_{R} includes a plurality of memory cells X₀₀ to Xᵢⱼ arranged like an array. One memory cell Xᵢⱼ includes a magnetoresistive effect element MTJᵢⱼ and a transistor (FET) Qᵢⱼ connected in series, where i is, for example, 0, 1, 2, . . . , 1023 and j is, for example, 0, 1, 2, . . . , 4095.

The magnetoresistive effect element MTJᵢⱼ includes first and second electrodes and the transistor Qᵢⱼ includes a current path having first and second terminals and a control terminal to control ON/OFF of the current path. The first terminal of the transistor Qᵢⱼ is connected to the first electrode of the magnetoresistive effect element MTJᵢⱼ.

A bit line BLⱼ is connected to the second electrode of the magnetoresistive effect element MTJᵢⱼ and extends in a first direction. The bit line BLⱼ is connected to the buffer memory M_{B}, that is, the sense amplifier SAⱼ. A source line SLⱼ is connected to the second terminal of the transistor Qᵢⱼ and extends in the first direction. A word line WLᵢ is connected to the control terminal of the transistor Qᵢⱼ and extends in a second direction perpendicular to the first direction.

A plurality of memory cells Xᵢ₀ to Xᵢⱼ connected to the word line WLᵢ belongs to one group, for example, a page PGᵢ. Data stored in the memory cells Xᵢ₀ to Xᵢⱼ in the page PGᵢ is page data.

A plurality of sense amplifiers SA₀ to SAⱼ is provided by corresponding to a plurality of columns CoL₀ to CoLⱼ.

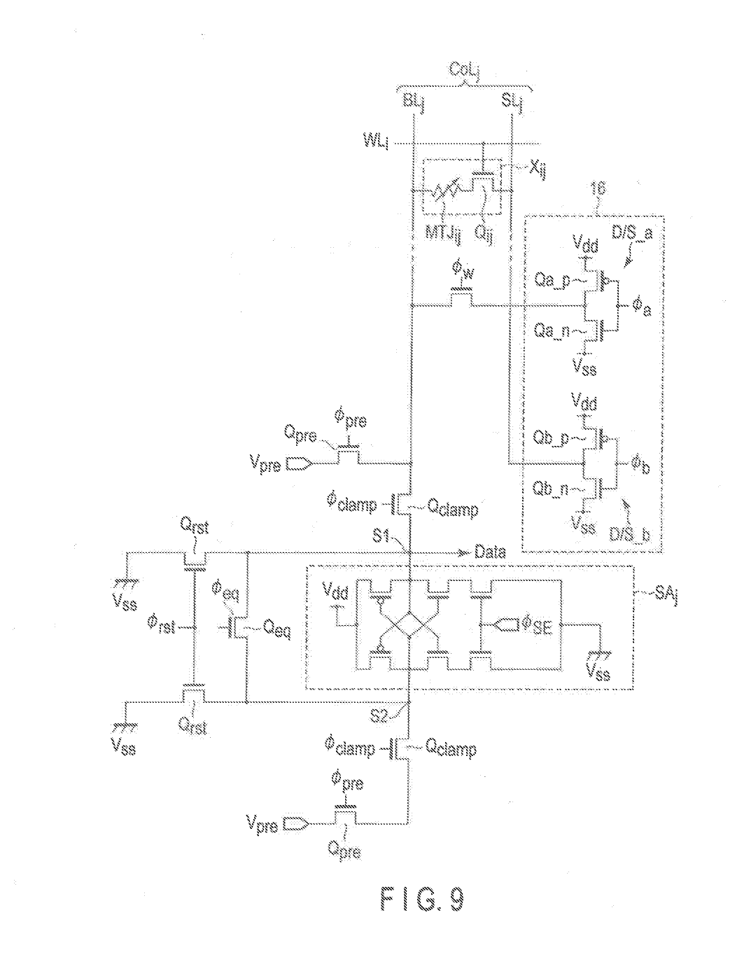

FIG. 9 shows an example of a sense amplifier of the redeem memory.

The memory cell Xᵢⱼ, the magnetoresistive effect element MTJᵢⱼ, the transistor Qᵢⱼ, the word line WLᵢ, the bit line BLⱼ, and the source line SLⱼ correspond to the memory cell Xᵢⱼ, the magnetoresistive effect element MTJᵢⱼ, the transistor Qᵢⱼ, the word line WLᵢ, the bit line BLⱼ, and the source line SLⱼ shown in FIG. 8 respectively.

Qₚᵣₑ and Q_{clamp} correspond to Qₚᵣₑ and Q_{clamp} in FIG. 7.

However, Qₚᵣₑ is a transistor (for example, an N channel FET) to apply the precharge potential Vₚᵣₑ to the bit line BLⱼ in a read operation and maintains OFF in a write operation.

Also, Q_{clamp} functions as a switching element (clamp circuit) to electrically connect the bit line BLⱼ to the sense amplifier SAⱼ. That is, Q_{clamp} maintains OFF in a write operation.

The sense amplifier SAⱼ is the same as the sense amplifier SAⱼ in FIG. 7.

However, the sense amplifier SAⱼ of the redeem memory M_{R} is used for read operation and is not used for write operation.

Q_{eq} and Qᵣₛₜ correspond to Q_{eq} and Qᵣₛₜ in FIG. 7. The function of these transistors Q_{eq}, Qᵣₛₜ is the same as that of the transistors Q_{eq}, Qᵣₛₜ in FIG. 7 and so the description thereof here is omitted.

The redeem memory M_{R} includes a write driver/sinker 16.

The write driver/sinker 16 includes a first driver/sinker D/S_a and a second driver/sinker D/S_b.

The first driver/sinker D/S_a is controlled by a control signal φₐ and includes a P channel FET Qa_p and an N channel FET Qa_n connected in series. The second driver/sinker D/S_b is controlled by a control signal φ_{b} and includes a P channel FET Qb_p and an N channel FET Qb_n connected in series.

When a control signal φ_{w} is activated in a write operation, the first driver/sinker D/S_a is electrically connected to the bit line BLⱼ.

When writing, for example, “0”, a write pulse is generated by setting the control signal φₐ to “0” and the control signal φ_{b} to “1”. “0” corresponds to the ground potential Vₛₛ and “1” corresponds to the power supply potential V_{dd}. This also applies below.

In such a case, a write current flows in a direction from the magnetoresistive effect element MTJᵢⱼ toward the transistor Tᵢⱼ and the magnetoresistive effect element MTJᵢⱼ changes to a low-resistance state. As a result, “0” is written into the memory cell Uᵢⱼ.

When writing “1”, a write pulse is generated by setting the control signal φₐ to “1” and the control signal φ_{b} to “0”.

In such a case, a write current flows in a direction from the transistor Tᵢⱼ toward the magnetoresistive effect element MTJᵢⱼ and the magnetoresistive effect element MTJᵢⱼ changes to a high-resistance state. As a result, “1” is written into the memory cell Uᵢⱼ.

In a read operation, on the other hand, the control signal φ_{w} is activated and the first driver/sinker D/S_a is electrically disconnected to the bit line BLⱼ. Also, the control signal φ_{b} is set to “1”. In this case, the ground potential Vₛₛ is applied to the source line SLⱼ.

### Memory Access Control

Examples of memory access controlling by the controller 14 in FIGS. 1 to 4 will be described.

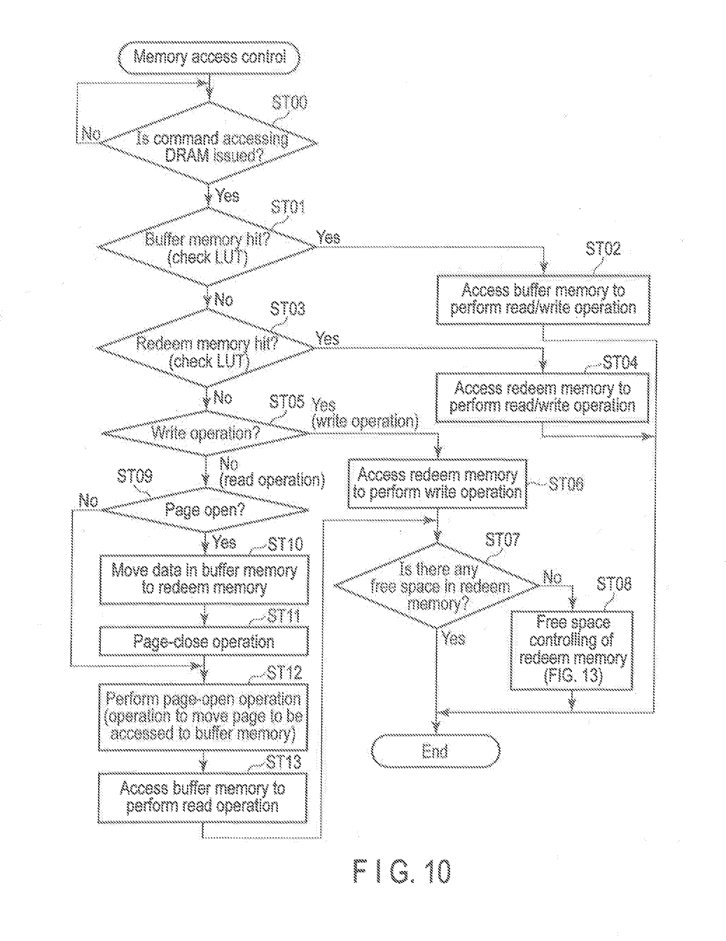

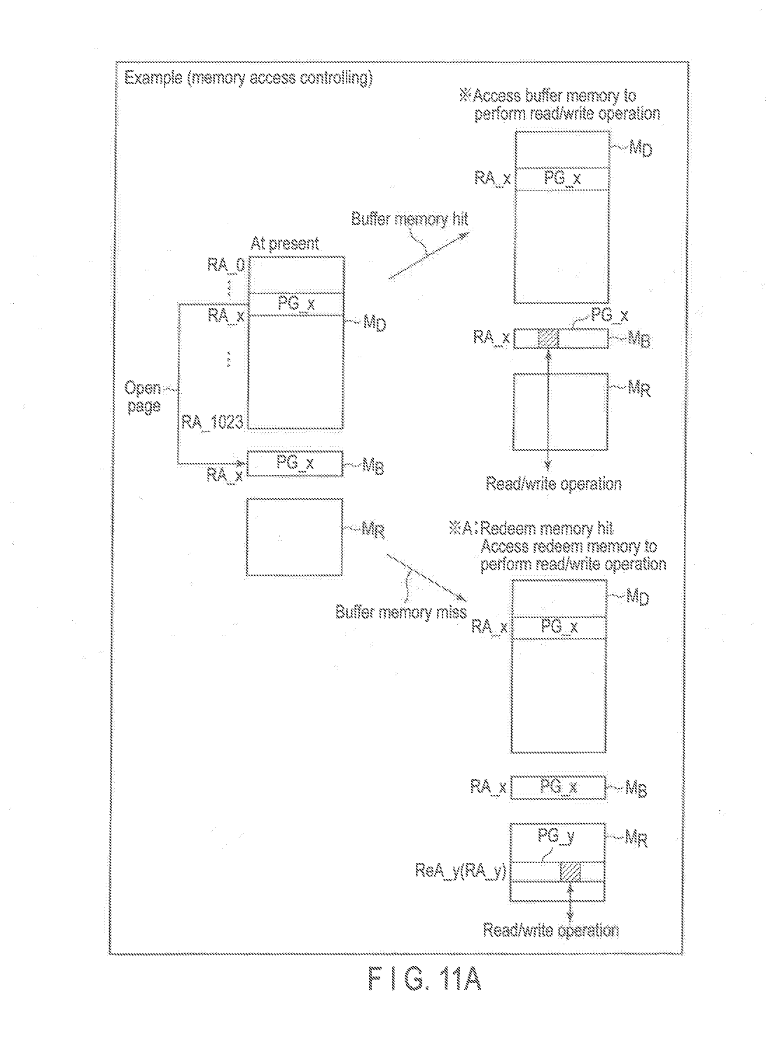

FIG. 10 is a flowchart showing an example of memory access controlling.

First, the controller 14 checks whether any command accessing DRAM is issued (step ST00).

If it is verified that a command accessing DRAM has been issued, the controller 14 checks whether data to be accessed is stored in the buffer memory based on the LUT 15 (step ST01).

If it is verified that data to be accessed is stored in the buffer memory (buffer memory hit), the controller 14 accesses the buffer memory to perform a read/write operation (step ST02).

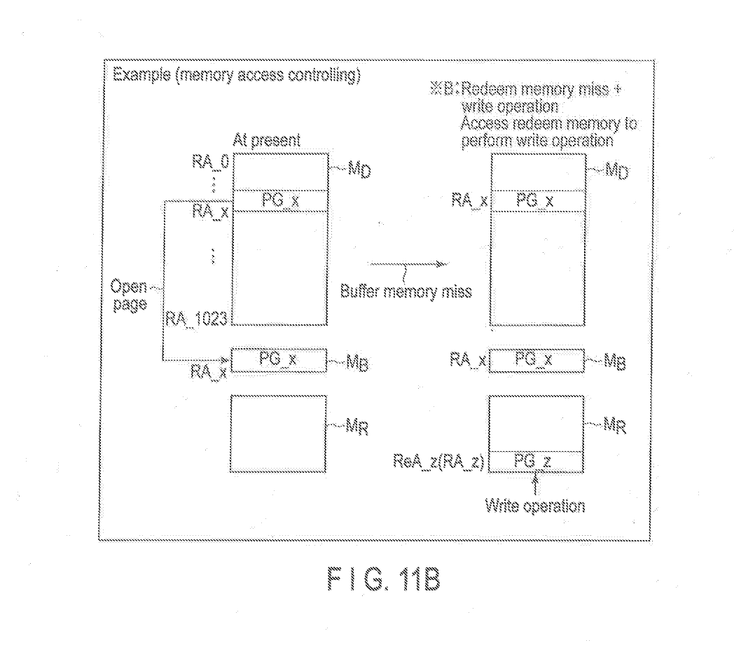

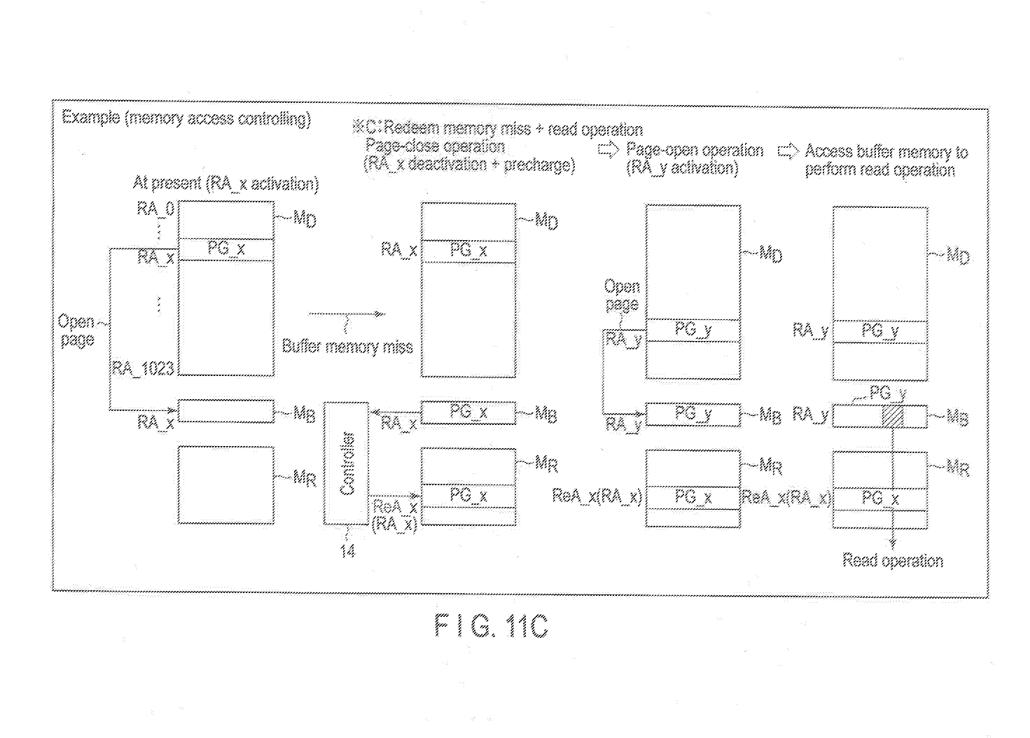

If, for example, as shown in FIG. 11A, data to be accessed is specified by a row address RA_x and data (page data) PG_x of the row address RA_x is read into the buffer memory M_{B}, the controller 14 can perform a read/write for all or a portion of the page data PG_x by accessing the buffer memory M_{B}.

On the other hand, if it is verified that data to be accessed is not stored in the buffer memory (buffer memory miss), the controller 14 checks whether data to be accessed is stored in the redeem memory based on the LUT 15 (step ST03).

If it is verified that data to be accessed is stored in the redeem memory (redeem memory hit), the controller 14 accesses the redeem memory to perform a read/write operation (step ST04).

If, for example, as shown in FIG. 11A, data to be accessed is specified by a row address RA_y and data (page data) PG_y of the row address RA_y is read to a row address ReA_y of the redeem memory M_{R}, the controller 14 can perform a read/write for all or a portion of the page data PG_y by accessing the row address ReA_y of the redeem memory M_{R}.

Incidentally, the order of step ST01 and step ST03 may be interchanged.

If it is verified that data to be accessed is not stored in the buffer memory (buffer memory miss) and is not stored in the redeem memory (redeem memory miss), the controller 14 checks whether the instruction from the processor is a write operation or a read operation (step ST05).

If the instruction from the processor is a write operation, the controller 14 accesses the redeem memory to perform a write operation (step ST06).

If, for example, as shown in FIG. 11B, data to be accessed is specified by a row address RA_z and data (page data) PG_z of the row address RA_z is not read into the buffer memory M_{B} and the redeem memory M_{R}, the controller 14 writes data at the row address RA_z to an address ReA_z of the redeem memory M_{R}.

Here, data in the buffer memory and the redeem memory is managed in units of pages or in units of masked pages.

For example, data read from DRAM into the buffer memory by a page-open operation is managed in units of pages. Also, data moved from the buffer memory to the redeem memory by a page-close operation is managed in units of pages. This is because all page data stored in the buffer memory or the redeem memory by taking such a route can be used as valid data.

In contrast, data written into the redeem memory by the processor in a write operation of a buffer memory miss or a redeem memory miss is managed in units of pages or in units of masked pages.

That is, when data is written into all bits in a page (row) to be accessed, all page data written into the redeem memory is valid data. Therefore, in this case, data written into the redeem memory is managed in units of pages.

When data is written into a portion of bits in a page (row) to be accessed, all page data written into the redeem memory is not valid data. For example, a case in which a portion of bits (valid data) in a page to be accessed is written into the redeem memory and the rest of bits (valid data) remains in DRAM can be considered.

Therefore, in this case, data written into the redeem memory is managed in units of masked pages. Managing data in units of masked pages means managing a portion of bits of page data as valid data and the rest of bits as invalid data (masked).

If a buffer memory miss and a redeem memory miss occur and the instruction from the processor is a write operation, after a write operation into the redeem memory is completed, the controller 14 checks whether there is any free space in the redeem memory (step ST07).

If there is no free space in the redeem memory due to the write operation into the redeem memory, the controller 14 executes memory space controlling of the redeem memory (step ST08).

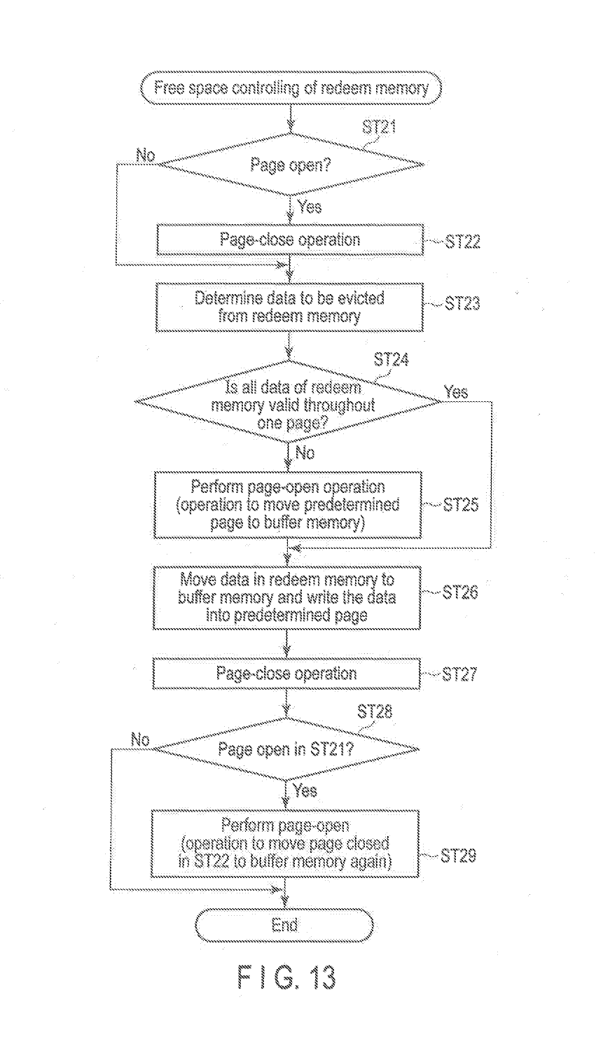

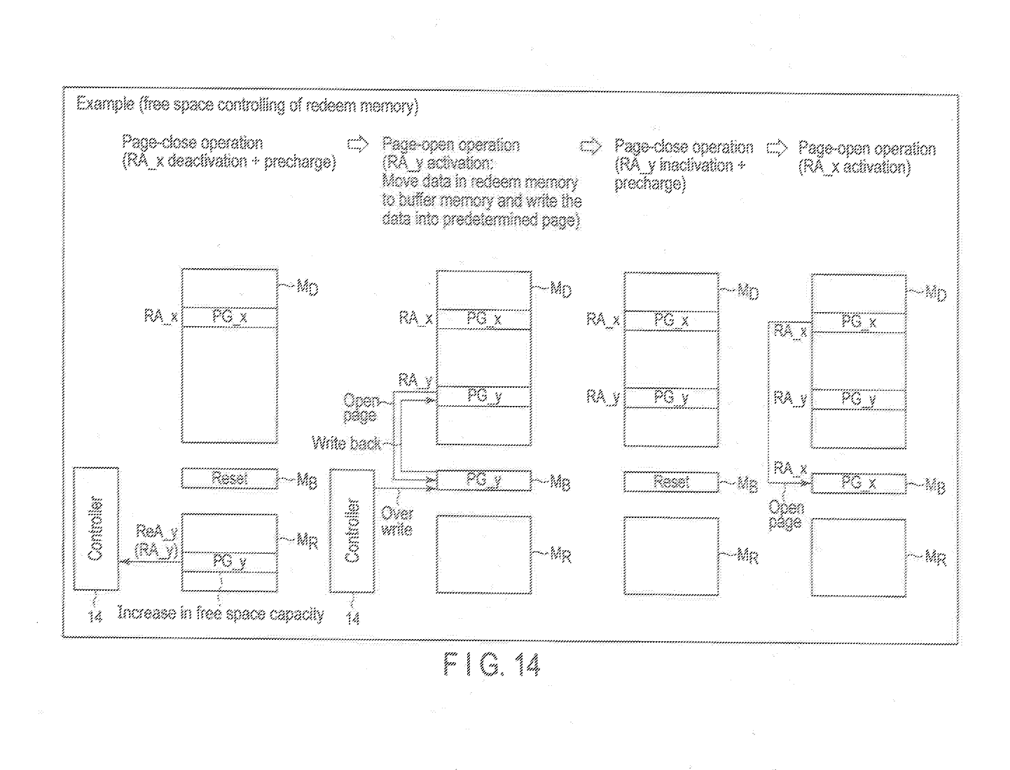

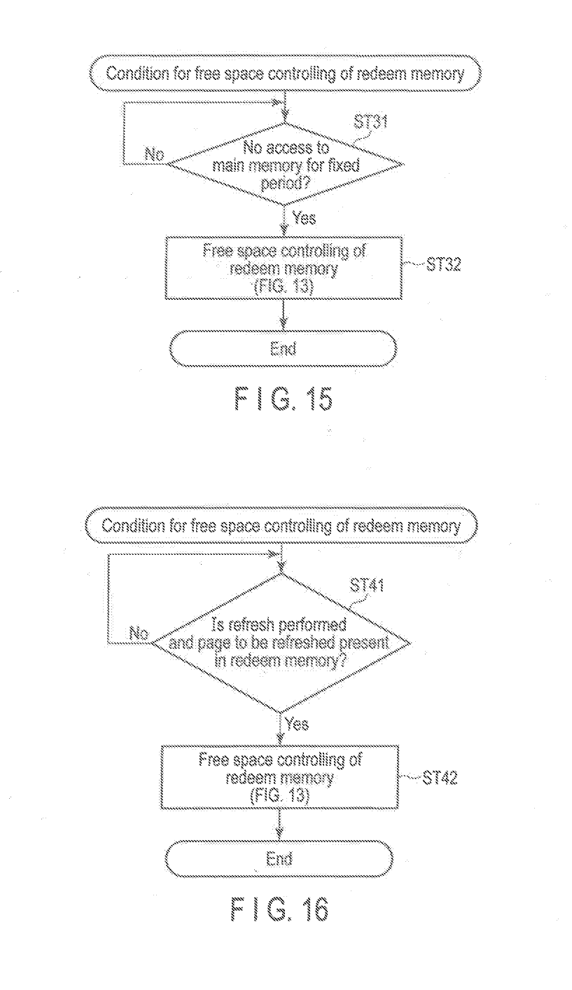

The memory space controlling of the redeem memory will be described with reference to FIG. 13.

First, the controller 14 checks whether DRAM is in a page-open state (step ST21). If DRAM is in a page-open state, the controller 14 performs a page-close operation (step ST22). Data (dirty data) stored in the buffer memory in a page-open state is written back into DRAM before a page-close operation is performed.

If, for example, as shown in FIG. 14, the page data PG_x at the row address RA_z is read into the buffer memory M_{B}, the controller 14 performs a page-close operation after writing the page data PG_x from the buffer memory M_{B} back to the DRAM M_{D}.

Next, the controller 14 determines data to be evicted from the redeem memory (step ST23).

Data to be evicted from the redeem memory is determined in units of row addresses of the redeem memory, that is, in units of pages or in units of masked pages.

For example, the controller 14 manages the usage frequency of data stored in the redeem memory in units of row addresses of the redeem memory. As the usage frequency, the index of, for example, MRU (most recently used) or LRU (least recently used) is used.

MRU means data most frequently used recently, that is, data having the minimum period from a final access time to a present time. LRU means data least frequently used recently, that is, data having the maximum period from a final access time to a present time.

The controller 14 selects data related to a row address containing LRU as an object to be evicted from the redeem memory, that is, as an object to be written from the redeem memory back to the DRAM.

Incidentally, step ST23 may be performed in parallel with steps ST21, ST22 or before these steps.

Next, the controller 14 checks whether data of the row address selected to be evicted from the redeem memory is all valid throughout one page (step ST24).

If data of the row address selected to be evicted from the redeem memory is not all valid throughout one page, that is, data of the row address selected to be evicted from the redeem memory is masked page data, the controller 14 accesses the row address of the DRAM corresponding to the row address based on LUT 15 to read page data from the DRAM into the buffer memory by a page-open operation (step ST25).

If, for example, as shown in FIG. 14, data of the row address ReA_y of the redeem memory M_{R} selected to be evicted is masked page data and the row address of the DRAM M_{D} corresponding to the row address ReA_y is RA_y, the controller 14 reads data at the row address RA_y from the DRAM M_{D} into the buffer memory M_{B}.

Then, the controller 14 moves data selected to be evicted from the redeem memory to the buffer memory (step ST26).

If, for example, step ST25 is not gone through, page data (valid data) is all transferred from the redeem memory to the buffer memory. If step ST25 is gone through, a portion of page data (valid data) is transferred from the redeem memory to the buffer memory to overwrite page data in the buffer memory therewith.

Data in the buffer memory is written back to DRAM.

Here, as shown in FIG. 14, data from the redeem memory M_{R} to the buffer memory M_{B} is preferably moved via the controller 14.

Then, a page-close operation is performed (step ST27).

If, for example, as shown in FIG. 14, the controller 14 performs a page-close operation after writing data at the row address RA_y from the buffer memory M_{B} back to the DRAM M_{D}.

Lastly, if DRAM is in a page-open state in step ST21, the controller 14 reads the page closed in step ST22 again from the DRAM into the buffer memory and performs a page-open operation to restore a state before the memory space controlling of the redeem memory is executed (steps ST28, ST29).

If, for example, as shown in FIG. 14, the row address closed in step ST22 is ReA_z, the controller 14 reads the page data PG_x at the row address RA_x from the DRAM M_{D} into the buffer memory M_{B}.

With the above steps, the memory space controlling of the redeem memory is completed.

The description returns to the memory access controlling in FIG. 10.

If a buffer memory miss and a redeem memory miss occur and the instruction from the processor is a read operation, the controller 14 accesses DRAM to perform a read operation (steps ST09 to ST13).

More specifically, first the controller 14 checks whether DRAM is in a page-open state (step ST09). If DRAM is in a page-open state, the controller 14 moves the page data read into the buffer memory to the redeem memory (step ST10). Also, the controller 14 creates LUT indicating a correspondence between the row address of DRAM and the row address of the redeem memory.

Data in the buffer memory is moved into the redeem memory because data read into the buffer memory is likely to be accessed again soon and thus, rather than writing back to DRAM, the data is more advantageously moved to the redeem memory without page-open/close operation and capable of high-speed access.

The controller 14 performs a page-close operation after moving page data from the buffer memory to the redeem memory (step ST11).

If, for example, as shown in FIG. 11C, the page data PG_x at the row address RA_x is read into the buffer memory M_{B}, the controller 14 performs a page-close operation after moving the page data PG_x from the buffer memory M_{B} to the redeem memory M_{R}. The page data PG_x is desirably written from the buffer memory M_{B} to the row address ReA_x of the redeem memory M_{R} via the controller 14.

Next, the controller 14 reads page data related to the row address of DRAM to be accessed from the DRAM into the buffer memory by a page-open operation (step ST12).

If, for example, as shown in FIG. 11C, the row address of DRAM to be accessed is RA_y, the controller 14 reads the page data PG_y related to the row address RA_y from the DRAM M_{D} into the buffer memory M_{B} by a page-open operation.

Then, the controller 14 accesses the buffer memory M_{B} to read data needed for the processor from the buffer memory M_{B} (step ST13).

If, for example, as shown in FIG. 11C, data needed by the processor, that is, data to be accessed is a portion of the page data PG_y, the controller reads the portion of the page data PG_y from the buffer memory M_{B}.

Thus, only if a buffer memory miss and a redeem memory miss occur and the instruction from the processor is a read operation, the DRAM is accessed to perform a page-open/close operation.

This means that, put another way, otherwise, that is, when a buffer memory hit (step ST01) occurs, a redeem memory hit (step ST03) occurs, or a buffer memory miss and a redeem memory miss occur and the instruction from the processor is a write operation, a page-open/close operation in DRAM is not currently performed and can be postponed.

Therefore, when the processor needs access to the main memory, a situation of a decreased access speed to the main memory is prevented by a page-open/close operation.

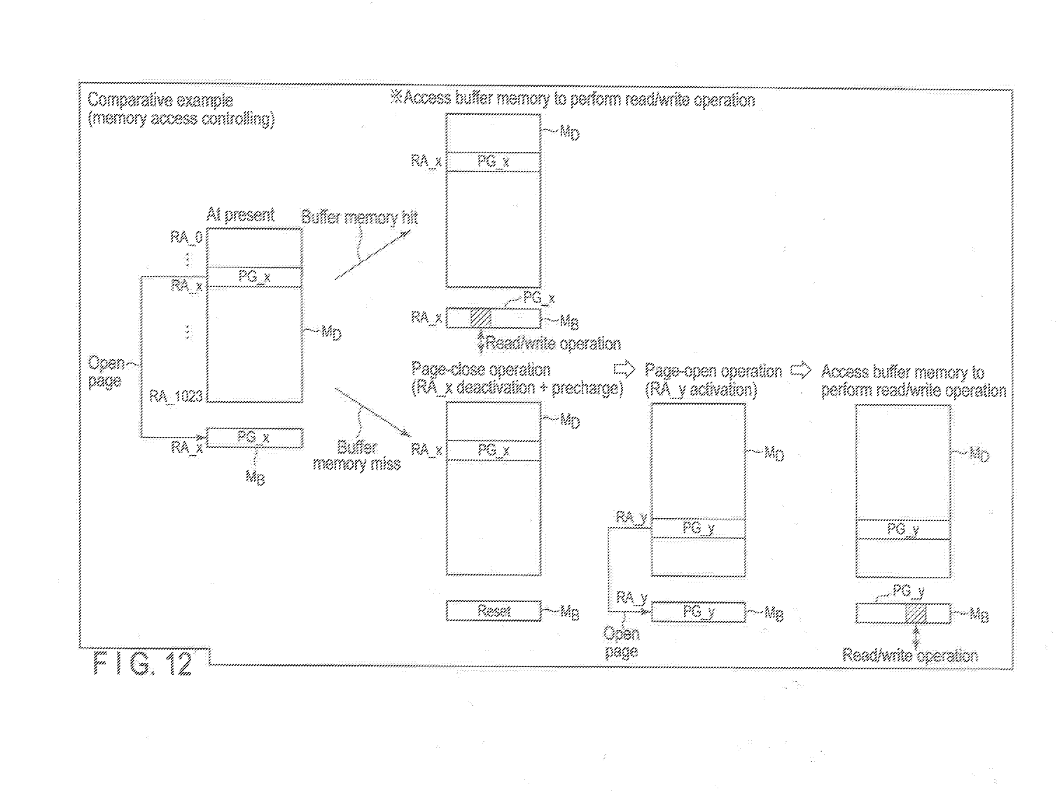

FIG. 12 shows a comparative example.

In the comparative example, if a buffer memory miss occurs, a page-open/close operation in DRAM always arises.

The present embodiment is characterized in that if the case of a buffer memory miss in FIG. 12 is divided into three cases of FIGS. 11A, 11B, and 11C, a page-open/close operation can be postponed, among these cases, in the cases of FIGS. 11A and 11B.

Lastly, the controller 14 checks whether there is any free space in the redeem memory (step ST07).

This is because if DRAM is in a page-open state in step ST09, the controller 14 moves page data in the buffer memory to the redeem memory and thus, there may be no free space in the redeem memory.

Therefore, by assuming a case in which there is no free space in the redeem memory, the controller 14 checks whether there is any free space in the redeem memory (step ST07) after reading data needed by the processor from the buffer memory (step ST13).

Then, if there is no free space in the redeem memory, as described above, the controller 14 executes memory space controlling (FIG. 13) of the redeem memory (step ST08).

With the above steps, the memory access controlling is completed.

In the above memory access controlling (FIG. 10), the memory space controlling (FIG. 13) of the redeem memory is executed when there is no free space in the redeem memory at time of step ST07.

However, the controller 14 can also execute the memory space controlling of the redeem memory in other cases.

If, for example, as shown in FIG. 15, there is no access from the processor to the main memory for a fixed period of time, the controller 14 may execute the memory space controlling (FIG. 13) of the redeem memory (steps ST31, ST32).

Also if, as shown in FIG. 16, refresh of DRAM is performed and a row address (page) to be refreshed is present in the redeem memory, the controller 14 can execute memory space controlling (FIG. 13) of the redeem memory (steps ST41, ST42).

Also, as described above, data stored in the redeem memory is dirty data. Therefore, data stored in the redeem memory needs to be made clean data in the end by writing back to DRAM as the formal storage location.

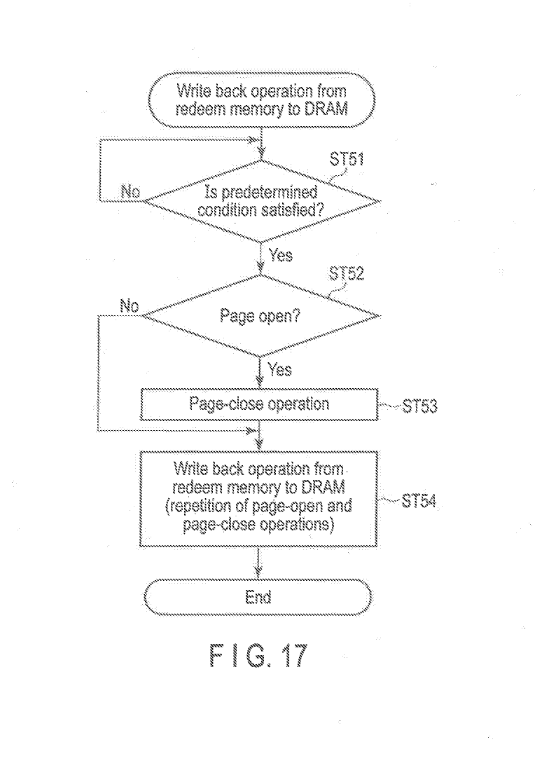

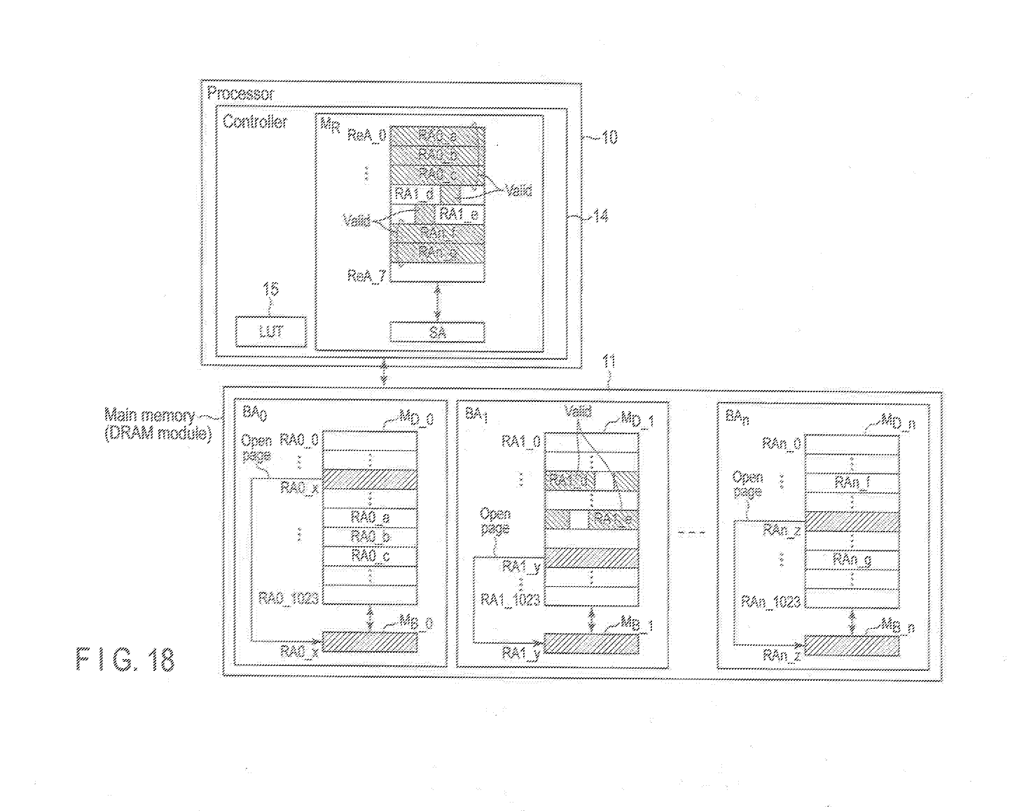

FIG. 17 shows an example of a write-back operation from the redeem memory to DRAM.

First, the controller 14 checks whether a predetermined condition is satisfied (steps ST51).

The predetermined condition is that, for example, the processor (a plurality of CPU cores) has entered a power save mode, among a plurality of CPU cores in the processor, the number of CPU cores in an operating state is equal to a predetermined number or less, the current throughput of data is a predetermined percentage or less when the maximum data throughput of the processor (a plurality of CPU cores) is 100%, or it becomes necessary to write back data is the DRAM to a storage device when power of the memory system (DRAM) is cut off or the like.

Next, if it is verified that the predetermined condition is satisfied, the controller 14 checks whether DRAM is in a page-open state (step ST52). If DRAM is in a page-open state, the controller 14 performs a page-close operation (step ST53). Data (dirty data) stored in the buffer memory in a page-open state is written back into DRAM before a page-close operation is performed.

Then, the controller 14 writes page data from the redeem memory back to DRAM in units of pages or in units of masked pages (step ST54).

When all page data in the redeem memory is written back to DRAM, the controller 14 repeatedly performs a page-open/close operation.

### Application Examples

FIGS. 18 to 21 show memory systems related to application examples.

These application examples are examples when the present example is applied to, for example, a conventional technology in which DRAM (including a buffer memory) is mounted on a memory module as DIMM (dual-inline memory module).

In the example of FIG. 18, a main memory (DRAM module) 11_{D} includes a plurality of banks BA₀, BA₁, . . . , BAₙ (n is a natural number equal to 2 or greater). For example, one bank BAₖ includes DRAM M_{D}_{_}ₖ and a buffer memory M_{B}_{_}ₖ, where k is one of 1 to n. One bank BAₖ may correspond to one package product (chip) or a plurality of banks BA₀, BA₁, . . . , BAₙ may be included in one package product or a plurality of package products.

The controller 14 is mounted inside the processor 10 and the redeem memory M_{R} is mounted inside the controller 14.

In such a case, for example, a conventional DRAM module is used as the main memory 11 and the present embodiment can be executed by changing the structure of the controller 14 and memory access controlling (algorithm).

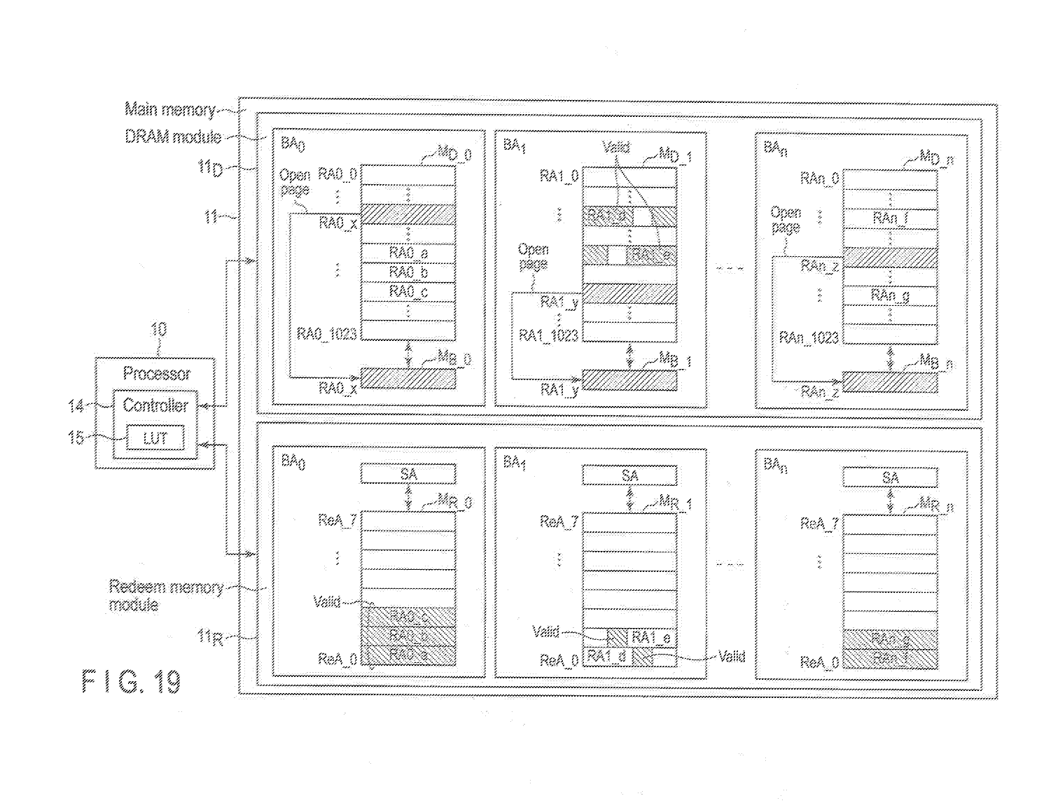

In the example of FIG. 19, the main memory 11 includes the DRAM module 11_{D} and a redeem memory module 11_{R}.

The DRAM module 11D includes a plurality of banks BA₀, BA₁, . . . , BAₙ. For example, one bank BAₖ includes DRAM M_{D}_{_}ₖ and a buffer memory M_{B}_{_}ₖ, where k is one of 1 to n. One bank BAₖ may correspond to one package product or the plurality of banks BA₀, BA₁, . . . , BAₙ may be included in one package product or a plurality of package products.

Also, the redeem memory module 11_{R} includes the plurality of banks BA₀, BA₁, . . . , BAₙ. For example, one bank BAₖ includes a redeem memory M_{R}_{_}ₖ and a sense amplifier (may also be used as a buffer memory) SAₖ, where k is one of 1 to n. One bank BAₖ may correspond to one package product or the plurality of banks BA₀, BA₁, . . . , BAₙ may be included in one package product or a plurality of package products.

In such a case, the present embodiment can be executed by newly adding the redeem memory module 11_{R} to the DRAM module ll_{D} as a conventional technology and changing the structure of the controller 14 and memory access controlling (algorithm).

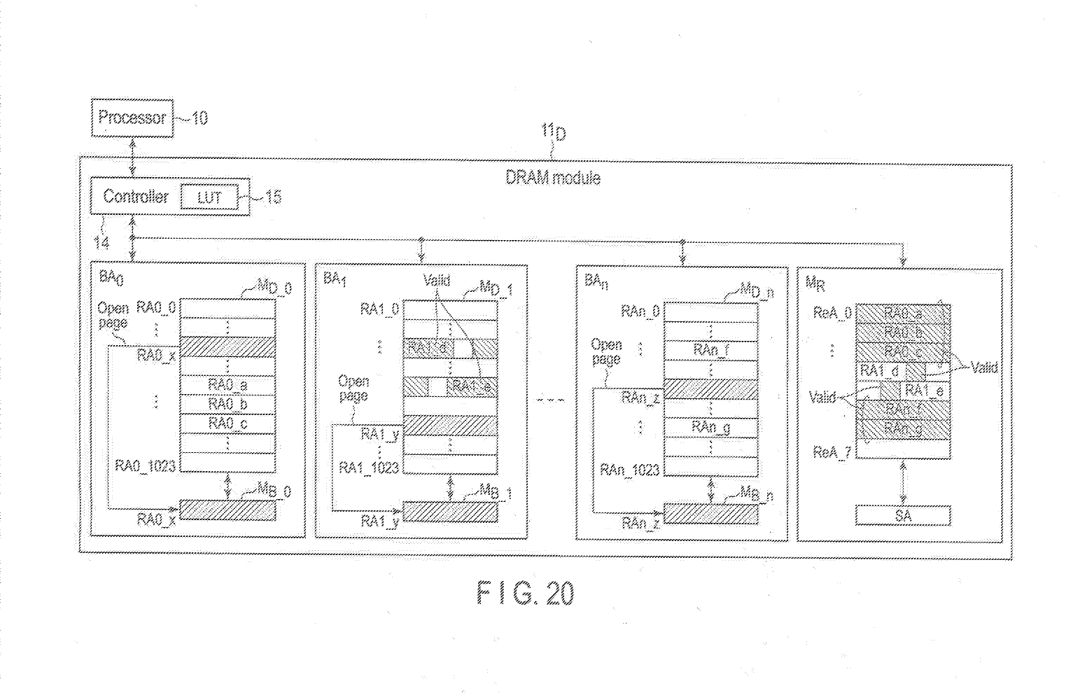

In the example of FIG. 20, the main memory (DRAM module) 11_{D} includes the controller 14, the plurality of banks BA₀, BA₁, . . . , BAₙ, and the redeem memory M_{R}.

The controller 14 corresponds to, for example, one package product.

One bank BAₖ includes, for example, the DRAM M_{D}_{_}ₖ and the buffer memory M_{B}_{_}ₖ, where k is one of 1 to n. One bank BAₖ may correspond to one package product or the plurality of banks BA₀, BA₁, . . . , BAₙ may be included in one package product or a plurality of package products.

The redeem memory M_{R} corresponds to, for example, one package product.

In such a case, the present example can be executed by combining the controller 14 and the redeem memory M_{R} inside the DRAM module 11_{D} and changing the structure of the controller 14 and memory access controlling (algorithm).

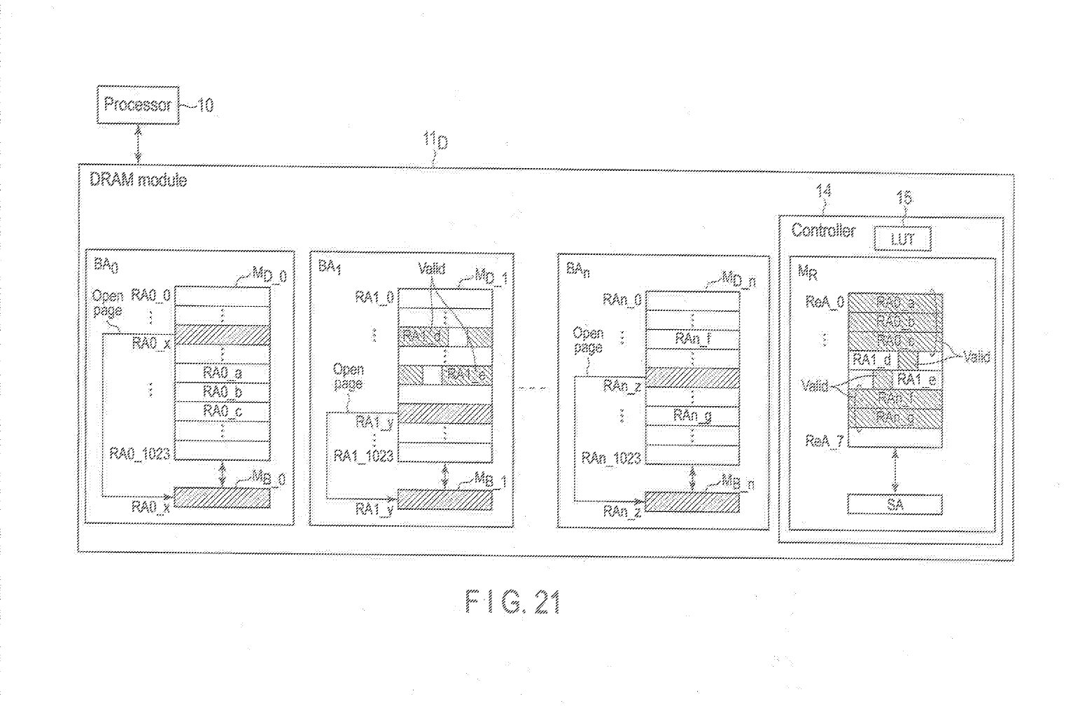

In the example of FIG. 21, the main memory (DRAM module) 11_{D} includes the controller 14 and the plurality of banks BA₀, BA₁, . . . , BAₙ. Also, the controller 14 includes the redeem memory M_{R}.

The controller 14 corresponds to, for example, one package product.

One bank BAₖ includes, for example, the DRAM M_{D}_{_}ₖ and the buffer memory M_{B}_{_}ₖ, where k is one of 1 to n. One bank BAₖ may correspond to one package product or the plurality of banks BA₀, BA₁, . . . , BAₙ may be included in one package product or a plurality of package products.

In such a case, the present embodiment can be executed by mounting the controller 14 including redeem memory M_{R} inside the DRAM module 11_{D} and changing the structure of the controller 14 and memory access controlling (algorithm).

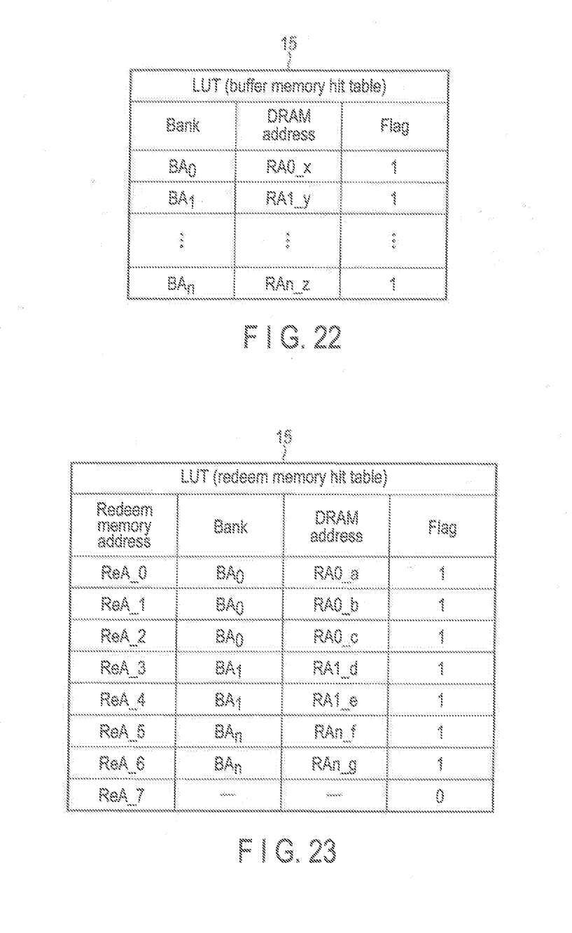

Each of FIGS. 22 to 24 shows an example of the LUT 15 inside the controller 14 in FIGS. 18 to 21.

FIG. 22 is an example of a buffer memory hit table,

The buffer memory hit table specifies whether page data is cached in the buffer memory M_{B} for each of the plurality of banks BA₀, BA₁, . . . , BAₙ and, when page data is cached in the buffer memory M_{B}, the DRAM address (row address) of page data cached in the buffer memory M_{B}.

If for example, page data of a row address RA0_z is read into the buffer memory M_{B} of the bank BA₀, the flag corresponding to the bank BA₀ is set to 1 and the DRAM address corresponding to the bank BA₀ becomes RA0_x.

Also, if page data of a row address RA0_y is read into the buffer memory M_{B} of the bank BA₁, the flag corresponding to the bank BA₁ is set to 1 and the DRAM address corresponding to the bank BA₁ becomes RA0_y.

Further, if page data of a row address RA0_z is read into the buffer memory M_{B} of the bank BAₙ, the flag corresponding to the bank BAₙ is set to 1 and the DRAM address corresponding to the bank BAₙ becomes RA0_z.

FIG. 23 is an example of a redeem memory hit table.

This table corresponds to application examples in FIGS. 18, 20, and 21.

That is, redeem addresses ReA_0, . . . , ReA_7 and DRAM addresses RA0_a, RA0_b, RA0_c, RA1_d, RA1_e, . . . , RAn_f, RAn_g shown in FIGS. 18, 20, and 21 and redeem addresses ReA_0, . . . , ReA_7 and DRAM addresses RA0_a, RA0_b, RA0_c, RA1_d, RA1_e, . . . , RAn_f, RAn_g shown in FIG. 23 correspond to each other.

The redeem memory hit table specifies to which row address of which DRAM (bank) page data stored at the address belongs for each of the plurality of redeem addresses (row addresses) ReA_0, ReA_1, . . . , ReA_7.

If, for example, page data stored at the redeem memory address ReA_0 is page data at the DRAM address (row address) RA0_a in the bank BA₀, the flag corresponding to the redeem memory address ReA_0 is 1, the bank corresponding to the redeem memory address ReA_0 is BA₀, and the DRAM address corresponding to the redeem memory address ReA_0 is RA0_a.

Also, if page data stored at the redeem memory address ReA_1 is page data at the DRAM address (row address) RA0_b in the bank BA₀, the flag corresponding to the redeem memory address ReA_1 is 1, the bank corresponding to the redeem memory address ReA_1 is BA₀, and the DRAM address corresponding to the redeem memory address ReA_1 is RA0_b.

Further, if page data stored at the redeem memory address ReA_6 is page data at the DRAM address (row address) RAn_g in the bank BAₙ, the flag corresponding to the redeem memory address ReA_6 is 1, the bank corresponding to the redeem memory address ReA_6 is BAₙ, and the DRAM address corresponding to the redeem memory address ReA_6 is RAn_g.

Incidentally, if no page data is stored at the redeem memory address ReA_7, that is, there is free space at the redeem memory address ReA_7, the flag corresponding to the redeem memory address ReA_7 is 0 and the bank and the DRAM address corresponding to the redeem memory address ReA_7 are invalid.

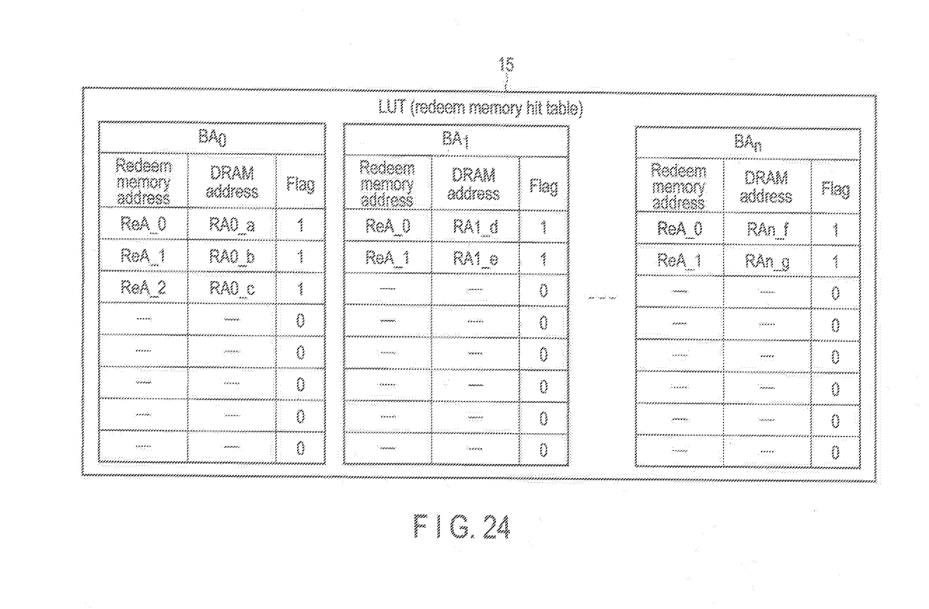

FIG. 24 is an example of the redeem memory hit table.

This table corresponds to the application example in FIG. 19.

That is, redeem addresses ReA_0, . . . , ReA_7 and DRAM addresses RA0_a, RA0_b, RA0_c, RA1_d, RA1_e, . . . , RAn_f, RAn_g shown in FIG. 19 and redeem addresses ReA_0, . . . , ReA_7 and DRAM addresses RA0_a, RA0_b, RA0_c, RA1_d, RA1_e, . . . , RAn_f, RAn_g shown in FIG. 24 correspond to each other.

In the application example of FIG. 19, there is a one-to-one correspondence between the plurality of banks BA₀, BA₁, . . . , BAₙ of the DRAM module 11_{D} and the plurality of banks BA₀, BA₁, . . . , BAₙ of the redeem memory module 11_{R}. Thus, the redeem memory hit table is provided for each bank.

In each bank, the redeem memory hit table specifies the relationship between the redeem memory address (row address) and the DRAM address.

If, for example, page data scored at the redeem memory address ReA_0 is page data at the DRAM address (row address) RA0_a in the bank BA₀, the flag corresponding to the redeem memory address ReA_0 is 1 and the DRAM address corresponding to the redeem memory address ReA_0 is RA0_a.

Also, if page data stored at the redeem memory address ReA_0 is page data at the DRAM address (row address) RA1_d in the bank BA₁, the flag corresponding to the redeem memory address ReA_0 is 1 and the DRAM address corresponding to the redeem memory address ReA_0 is RA1_d.

Further, if page data stored at the redeem memory address ReA_0 is page data at the DRAM address (row address) RAn_f in the bank BA_n, the flag corresponding to the redeem memory address ReA_0 is 1 and the DRAM address corresponding to the redeem memory address ReA_0 is RAn_f.

Incidentally, if no page data is stored at the redeem memory address, that is, there is free space at the redeem memory address in each bank, the flag corresponding to the redeem memory address is 0 and the DRAM address corresponding to the redeem memory address is invalid.

### Summary

According to the embodiment, as described above, the data transfer capability between the processor and the main memory can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a first memory including a first address;
a second memory being capable of storing data corresponding to the first address of the first memory;
a third memory; and
a controller controlling an access to the first, second and third memories,
wherein the controller is configured to:
execute a second access to the second memory instead of a first access in a first case, where the first case is a case in which a command for executing the first access to the first address is issued and the data corresponding to the first address is stored in the second memory;
execute a third access to a second address of the third memory instead of the first access in a second case, where the second case is a case in which the command is issued and the data corresponding to the first address is stored in the second address of the third memory; and
execute a fourth access to a third address of the third memory instead of the first access in a third case, where the third case is a case in which the command is issued, the command indicates a write operation to the first address and the first and second cases are excluded.

2. The system of claim 1, wherein
the data corresponding to the first address is not stored in the third memory when the data corresponding to the first address is stored in the second memory, and
the data corresponding to the first address is not stored in the second memory when the data corresponding to the first address is stored in the third memory.

3. The system of claim 1, wherein
the controller is configured to read the data corresponding to the first address into the second memory in a fourth case, where the fourth case is a case in which the command is issued, the command indicates a read operation from the first address and the first and second cases are excluded.

4. The system of claim 3, wherein
the controller is configured to transfer data stored in the second memory to the third memory before the data corresponding to the first address is read into the second memory in the fourth case.

5. The system of claim 4, wherein
the data stored in the second memory is transferred to the third memory through the controller.

6. The system of claim 1, wherein
the controller is configured to transfer data stored in the third memory to the first memory when the predetermined condition is satisfied.

7. The system of claim 6, wherein
the predetermined condition is that the third memory has no memory space.

8. The system of claim 7, wherein
the controller is configured to check about whether the predetermined condition is satisfied every time a write operation to the third memory is executed in a case other than the first and second cases.

9. The system of claim 6, wherein
the data transferred to the first memory includes data in which a period from a final access time to a present time is the maximum.

10. The system of claim 6, wherein
the predetermined condition is one of that an access to the first memory does not occur during a fixed period and that a refresh is executed in the first memory and data as a target of the refresh is stored in the third memory.

11. The system of claim 6, further comprising:
CPU cores,
the predetermined condition is one of that the CPU cores enter in a low consumption mode, that a number of the CPU cores in a operation state among the CPU cores is equal to or smaller than a predetermined number, that a data processing quantity in a present time is equal to or smaller than a predetermined percentage when the maximum of the data processing quantity of the CPU cores is 100%, and that an instruction of switching off a power source of the first memory is indicated.

12. The system of claim 1, wherein
the controller comprises a table for checking about whether the data corresponding to the first address is stored in the second memory.

13. The system of claim 1, wherein
the controller comprises a table for checking about whether the data corresponding to the first address is stored in the third memory, and about a relationship between the first address and the second address when the data corresponding to the first address is stored in the second address of the third memory.

14. The system of claim 1, wherein
each of the first, second and third addresses is an address which indicates data with a predetermined unit.

15. The system of claim 1, wherein
the second memory functions as a sense amplifier of the first memory.

16. The system of claim 1, wherein
a memory capacitance of the third memory is larger than a memory capacitance of the second memory.

17. The system of claim 1, wherein
the controller is provided in a processor.

18. A processor system comprising:
a first memory including a first address;
a second memory being capable of storing data corresponding to the first address of the first memory;
a third memory;
a controller controlling an access to the first, second and third memories; end
a processor including a CPU core,
wherein the controller is configured to:
execute a second access to the second memory instead of a first access in a first case, where the first case is a case in which a command for executing the first access to the first address is issued by the processor and the data corresponding to the first address is stored in the second memory;
execute a third access to a second address of the third memory instead of the first access in a second case, where the second case is a case in which the command is issued by the processor and the data corresponding to the first address is stored in the second address of the third memory; and
execute a fourth access to a third address of the third memory instead of the first access in a third case, where the third case is a case in which the command is issued by the processor, the command indicates a write operation to the first address and the first and second cases are excluded.

19. A memory system comprising:
a first memory including a first address;
a second memory being capable of storing data corresponding to the first address of the first memory;
a third memory; and
a controller controlling an access to the first, second and third memories on the basis of a command for accessing to the first memory,
wherein the second and third memory are cache memories of the first memory, and are provided in the same memory hierarchy,
the data corresponding to the first address is not stored in the third memory when the data corresponding to the first address is stored in the second memory, and
the data corresponding to the first address is not stored in the second memory when the data corresponding to the first address is stored in the third memory.

20. A processor system comprising:
a first memory including a first address;
a second memory being capable of storing data corresponding to the first address of the first memory;
a third memory;
a controller controlling an access to the first, second and third memories on the basis of a command for accessing to the first memory; and
a processor issuing the command,
wherein the second and third memory are cache memories of the first memory, and are provided in the same memory hierarchy,
the data corresponding to the first address is not stored in the third memory when the data corresponding to the first address is stored in the second memory, and
the data corresponding to the first address is not stored in the second memory when the data corresponding to the first address is stored in the third memory.
